(19) United States
(12) Patent Application Publication
(10) Pub. No.: US 2016/0172620 A1
(43) Pub. Date: Jun. 16, 2016

(54) ORGANIC ELECTROLUMINESCENCE ELEMENT AND METHOD OF MANUFACTURING THE SAME

(71) Applicant: JOLED INC., Tokyo (JP)

(72) Inventors: Jun HASHIMOTO, Tokyo (JP); Hiroyuki AJIKI, Tokyo (JP); Hideyuki SHIRAHASE, Tokyo (JP)

(73) Assignee: JOLED INC., Tokyo (JP)

(21) Appl. No.: 14/962,240

(22) Filed: Dec. 8, 2015

(30) Foreign Application Priority Data
Dec. 11, 2014 (JP) 2014-251052

(51) Int. Cl. H01L 51/52; H01L 51/50; H01L 51/56

(52) U.S. Cl. CPC H01L 51/5218; H01L 51/56; H01L 51/5234; H01L 51/5076; H01L 51/5092

(57) ABSTRACT

An organic EL element includes: a light-reflective anode; light-emitting layer above the anode; functional layer on the light-emitting layer; and light-transmissive cathode on the functional layer and including metal layer. The functional layer includes: fluorine compound layer including fluorine compound including first metal being alkali metal or alkaline-earth metal; and an electron transport layer on the fluorine compound layer and having electron transport property. The electron transport layer includes organic material having electron transport property, and is doped with second metal being alkali metal or alkaline-earth metal and has property of cleaving bond between the first metal and fluorine in the compound. The electron transport layer has first and second regions, the first region contacts the fluorine compound layer, and the second region is closer to the cathode than the first region is, and the first region has concentration of the second metal higher than the second region has.

### BACKGROUND OF THE DISCLOSURE

This application is based on an application No. 2014-251052 filed in Japan, the contents of which are hereby incorporated by reference.

(1) Technical Field

The present disclosure relates to an organic electroluminescence (EL) element and a method of manufacturing the organic EL element.

(2) Description of Related Art

In recent years, display devices employing an organic EL element have been becoming widespread owing to characteristics of the organic EL element such as a high visibility resulting from self-luminescence and an excellent shock resistance resulting from a fully solid-state structure thereof.

According to a structure of the organic EL element, at least a light-emitting layer is interposed between a pair of electrodes (an anode and a cathode). Further, the organic EL element mostly includes a functional layer (an electron transport layer, an electron injection layer, and so on) that is interposed between the light-emitting layer and the cathode for supplying electrons to the light-emitting layer. Also, it is known that an excellent electron injection property is exhibited by the functional layer made of an alkali metal or an alkaline-earth metal having a low work function.

However, an alkali metal and an alkaline-earth metal are easy to react with impurities such as moisture and oxygen. For this reason, impurities degrade the functional layer, which includes an alkali metal or an alkaline-earth metal. This might exercise an adverse effect such as degradation of luminous efficiency and reduction of light-emitting lifetime of the organic EL element.

Japanese Patent No. 4882508 discloses an organic EL element including an inorganic barrier layer on a light-emitting layer in order to prevent degradation of a functional layer. Such an inorganic barrier layer ensures a property of blocking impurities, and prevents the functional layer from being degraded by impurities that are absorbed onto a surface of the light-emitting layer which is formed prior to the inorganic barrier layer.

Here, the luminous efficiency is determined by a product of internal quantum efficiency by light-extraction efficiency. The internal quantum efficiency is represented by a ratio of the number of photons generated inside the organic EL element to the number of electrons injected into the organic EL element. The light-extraction efficiency is represented by a ratio of the number of photons emitted outside the organic EL element to the number of photons generated inside the organic EL element.

### SUMMARY OF THE DISCLOSURE

The present disclosure aims to provide an organic EL element and a method of manufacturing the organic EL element according to which a sufficient property of blocking impurities, an excellent internal quantum efficiency, and an improved light-extraction efficiency are exhibited.

In order to achieve the above aim, an organic EL element relating to one aspect of the present disclosure comprises: a light-reflective anode; a light-emitting layer that is disposed above the anode; a functional layer that is disposed on the light-emitting layer; and a light-transmissive cathode that is disposed on the functional layer, and includes a metal layer, wherein the functional layer includes: a fluorine compound layer that includes a fluorine compound including a first metal that is an alkali metal or an alkaline-earth metal; and an electron transport layer that is disposed on the fluorine compound layer, and has an electron transport property, the electron transport layer includes an organic material, and is doped with a second metal, the organic material having an electron transport property, the second metal being an alkali metal or an alkaline-earth metal, the electron transport layer has a first region and a second region, the first region is in contact with the fluorine compound layer, and the second region is closer to the cathode than the first region is, and the first region has a concentration of the second metal higher than the second region has.

According to the organic EL element relating to the above aspect, it is possible to exhibit a sufficient property of blocking impurities, an excellent internal quantum efficiency, and an improved light-extraction efficiency.

### BRIEF DESCRIPTION OF THE DRAWINGS

These and other objects, advantages, and features of the technology pertaining to the present disclosure will become apparent from the following description thereof taken in conjunction with the accompanying drawings, which illustrate at least one specific embodiment of the technology pertaining to the present disclosure.

FIG. 1 is a cross-sectional view schematically showing a structure of an organic EL element relating to an embodiment.

FIG. 2A is a graph showing luminance retention that varies in accordance with variation of thickness of an interlayer, FIG. 2B is a graph showing luminous efficiency ratio that varies in accordance with variation of the thickness of the interlayer.

FIG. 3 explains optical interference that occurs in an optical cavity formed in the organic EL element.

FIG. 4 is a graph showing results of an index luminance/y of blue light extracted from a blue organic EL element that was calculated through simulation performed by varying optical thickness of the functional layer.

FIG. 5 is a graph showing the index luminance/y of blue light extracted from the blue organic EL element that was calculated through simulation while varying the total thickness of a light-emitting layer and the functional layer from 5 nm to 200 nm.

FIG. 6A is a graph showing actual efficiency of the index luminance/y of blue light that varies in accordance with variation of the optical thickness of the functional layer, and FIG. 6B is a graph showing the index luminance/y of blue light that was calculated through simulation by varying the total thickness of the light-emitting layer and the functional layer from 5 nm to 200 nm and the index luminance/y of blue light that is estimated from actual efficiency of each different value of the total thickness.

FIGS. 7A-7C are partial cross-sectional views schematically showing a manufacturing process of the organic EL element relating to the embodiment, where FIG. 7A shows a state in which a TFT layer and an interlayer insulating layer are formed on a base material, FIG. 7B shows a state in which a pixel electrode is formed on the interlayer insulating layer, and FIG. 7C shows a state in which a barrier rib material layer is formed on the interlayer insulating layer and the pixel electrode.

FIGS. 8A-8C are partial cross-sectional views schematically showing the manufacturing process of the organic EL element relating to the embodiment, continuing from FIG. 7C, where FIG. 8A shows a state in which a barrier rib layer is formed, FIG. 8B shows a state in which a hole injection layer is formed on the pixel electrode within an opening of the barrier rib layer, and FIG. 8C shows a state in which a hole transport layer is formed on the hole injection layer within the opening of the barrier rib layer.

FIGS. 9A-9C are partial cross-sectional views schematically showing the manufacturing process of the organic EL element relating to the embodiment, continuing from FIG. 8C, where FIG. 9A shows a state in which a light-emitting layer is formed on the hole transport layer within the opening of the barrier rib layer, FIG. 9B shows a state in which an interlayer is formed on the light-emitting layer and the barrier rib layer, and FIG. 9C shows a state in which a metal doped region of an electron transport layer is formed on the interlayer.

FIGS. 10A-10D are partial cross-sectional views schematically showing the manufacturing process of the organic EL element relating to the embodiment, continuing from FIG. 9C, where FIG. 10A shows a state in which a metal non-doped region of the electron transport layer is formed on the metal doped region of the electron transport layer, FIG. 10B shows a state in which an electron injection layer is formed on the metal non-doped region of the electron transport layer, FIG. 10C shows a state in which a counter electrode is formed on the electron injection layer, and FIG. 10D shows a state in which a sealing layer is formed on the counter electrode.

FIG. 11 is a flow chart schematically showing the manufacturing process of the organic EL element relating to the embodiment.

FIG. 12 is a block diagram showing a structure of an organic EL display device including the organic EL element relating to the embodiment.

### DESCRIPTION OF EMBODIMENT

### Process by which the Present Disclosure was Achieved

According to the organic EL element disclosed in Japanese Patent No. 4882508, the inorganic barrier layer is made of insulator, semiconductor, or metal having a work function of 4.0 eV or higher, and has a low electron injection property. Accordingly, sufficient electrons are not supplied to the light-emitting layer, and accordingly an excellent internal quantum efficiency might not be exhibited.

Also, since a metal generally has a high extinction coefficient, inclusion of an alkali metal or an alkaline-earth metal in a functional layer hampers improvement of the light-extraction efficiency.

In view of the above problem, the inventors studied an organic EL element and a manufacturing method of the organic EL element according to which a sufficient property of blocking impurities, an excellent internal quantum efficiency, and an improved light-extraction efficiency are exhibited.

<Aspects of the Disclosure>

An organic EL element relating to one aspect of the present disclosure comprises: a light-reflective anode; a light-emitting layer that is disposed above the anode; a functional layer that is disposed on the light-emitting layer; and a light-transmissive cathode that is disposed on the functional layer, and includes a metal layer, wherein the functional layer includes: a fluorine compound layer that includes a fluorine compound including a first metal that is an alkali metal or an alkaline-earth metal; and an electron transport layer that is disposed on the fluorine compound layer, and has an electron transport property, the electron transport layer includes an organic material, and is doped with a second metal, the organic material having an electron transport property, the second metal being an alkali metal or an alkaline-earth metal, the electron transport layer has a first region and a second region, the first region is in contact with the fluorine compound layer, and the second region is closer to the cathode than the first region is, and the first region has a concentration of the second metal higher than the second region has.

Here, the “metal layer” may be a layer made of a simple substance of a metal element such as Ag and Al, or a layer made of alloy of a plurality of metal elements.

The fluorine compound including the first metal which is an alkali metal or an alkaline-earth metal has a high property of blocking impurities. Accordingly, the fluorine compound layer, which includes the fluorine compound, prevents intrusion of impurities from the light-emitting layer into the electron transport layer, and thereby prevents degradation of the electron transport layer. According to the above aspect, therefore, it is possible to suppress occurrence of an adverse effect such as degradation of the luminous efficiency and reduction of the light-emitting lifetime.

Also, the second metal, which is included in the first region of the electron transport layer in contact with the fluorine compound layer, is an alkaline metal or an alkaline-earth metal. The second metal cleaves the bond between the first metal and fluorine in the fluorine compound including the first metal included in the fluorine compound layer, to liberate the first metal. The liberated first metal is an alkali metal or an alkaline-earth metal, and accordingly has a low work function and a high electron injection property. According to the above aspect, therefore, it is possible to exhibit an excellent electron supply property from the electron transport layer to the light-emitting layer, thereby exhibiting an excellent internal quantum efficiency.

Also, the entire electron transport layer does not include the second metal at a uniform concentration. The second region of the electron transport layer includes the second metal at a lower concentration than the first region of the electron transport layer includes. Accordingly, it is possible to suppress light absorption in the entire electron transport layer compared with the case where the entire electron transport layer includes the second metal at the same concentration as the first region. According to the above aspect, therefore, it is possible to improve the light-extraction efficiency.

According to the above aspect, therefore, it is possible to exhibit a sufficient property of blocking impurities, an excellent internal quantum efficiency, and an improved light-extraction efficiency.

Also, the first region may include the second metal, and the second region may not include the second metal.

According to the above aspect, it is possible to suppress light absorption in the second region, thereby improving the light-extraction efficiency.

The first metal may be sodium. According to this aspect, the fluorine compound layer has an excellent property of blocking impurities because of including sodium fluoride having a low hygroscopicity and a low reactivity with oxygen. Also, since sodium has a low work function, the fluorine compound layer has an excellent electron injection property from the fluorine compound layer to the light-emitting layer.

The second metal may be barium. Since barium is a versatile material, it is possible to achieve cost reduction by forming the functional layer from barium.

Also, the light-emitting layer may emit blue light, an optical cavity may be formed between the anode and the cathode, and the functional layer may have a thickness at which a secondary interference of the blue light occurs in the optical cavity.

Here, the “thickness of the functional layer at which the secondary interference of the blue light occurs in the optical cavity” indicates the second smallest one of values of the thickness of the functional layer that corresponds to a local maximum of an index luminance/y that occurs due to optical interference in an optical cavity, where luminance and y are luminance and a value y in an x-y chromaticity of the blue light extracted from the organic EL element, respectively.

In the case where the metal layer is included in the cathode, if metal elements diffuse into a light-emitting layer during a manufacturing process of the metal layer, impurity level occurs in the light-emitting layer, and internal quantum efficiency might degrade. For this reason, in the case where the metal layer is included in the cathode in the organic EL element emitting blue light, the internal quantum efficiency is considered to degrade due to plasmon loss.

According to the organic EL element relating to the above aspect, the secondary interference occurs in the optical cavity. Accordingly, the thickness of the functional layer at which the secondary interference occurs is larger than the thickness of the functional layer at which the primary interference occurs. According to the above aspect, therefore, it is possible to make the light-emitting layer distant from the cathode, thereby suppressing diffusion of elements during the manufacturing process of the metal layer and plasmon loss, and as a result exhibiting an excellent internal quantum efficiency.

Also, the thickness of the functional layer may be set so as to correspond to an index luminance/y that is equal to or higher than a local maximum of the index luminance/y at a primary interference according to characteristics of the index luminance/y that varies in accordance with variation of the thickness of the functional layer, where luminance and y are luminance and a value y in an x-y chromaticity of the blue light extracted from the organic EL element, respectively.

According to the above aspect, blue light having a high index luminance/y is extracted from the blue organic EL element. Therefore, it is possible to effectively extract blue light having an excellent color purity.

Also, the functional layer may further include an electron injection layer that is disposed on the electron transport layer, and has an electron injection property. According to this, it is possible to improve an electron injection property from the cathode, thereby exhibiting an excellent internal quantum efficiency.

A manufacturing method of an organic EL element relating to one aspect of the present disclosure comprises: forming a light-reflective anode; forming, above the anode, a light-emitting layer; forming, on the light-emitting layer, a fluorine compound layer that includes a fluorine compound including a first metal that is an alkali metal or an alkaline-earth metal; forming, on the fluorine compound layer, an electron transport layer from an organic material that has an electron transport property; and forming, above the electron transport layer, a light-transmissive cathode that includes a metal layer, wherein in the forming the electron transport layer, a first region of the electron transport layer is doped with a second metal at a higher concentration than a second region of the electron transport layer is, the first region being in contact with the fluorine compound layer, and the second region being above the first region, the second metal being an alkali metal or an alkaline-earth metal.

According to the organic EL element manufactured by the above manufacturing method, the fluorine compound layer, which includes the fluorine compound including the first metal, blocks intrusion of impurities from the light-emitting layer into the electron transport layer, and thereby prevents degradation of the electron transport layer. According to the above manufacturing method, therefore, it is possible to manufacture the organic EL element in which occurrence of an adverse effect is suppressed such as degradation of the luminous efficiency and reduction of the light-emitting lifetime.

Also, the second metal, which is included in the first region of the electron transport layer which is in contact with the fluorine compound layer, is an alkaline metal or an alkaline-earth metal. The second metal cleaves the bond between the first metal and fluorine in the fluorine compound including the first metal included in the fluorine compound layer to liberate the first metal. The liberated first metal is an alkali metal or an alkaline-earth metal, and has a low work function and a high electron injection property. According to the above manufacturing method, therefore, it is possible to manufacture the organic EL element that exhibits an excellent electron supply property from the electron transport layer to the light-emitting layer, thereby exhibiting an excellent internal quantum efficiency.

Also, the entire electron transport layer does not include the second metal at a uniform concentration. The second region of the electron transport layer includes the second metal at a lower concentration than the first region of the electron transport layer includes. Accordingly, it is possible to suppress light absorption in the entire electron transport layer compared with the case where the entire electron transport layer includes the second metal at the same concentration as the first region. According to the above manufacturing method, therefore, it is possible to manufacture the organic EL element that exhibits a high light-extraction efficiency.

### Embodiment

The following explains an organic EL element relating to an embodiment of the present disclosure. The following explanation is just an example for explaining a structure relating to one aspect of the present disclosure and effects thereof, and accordingly the present disclosure except the essence thereof is not limited to the embodiment explained below.

[1. Structure of Organic EL Element]

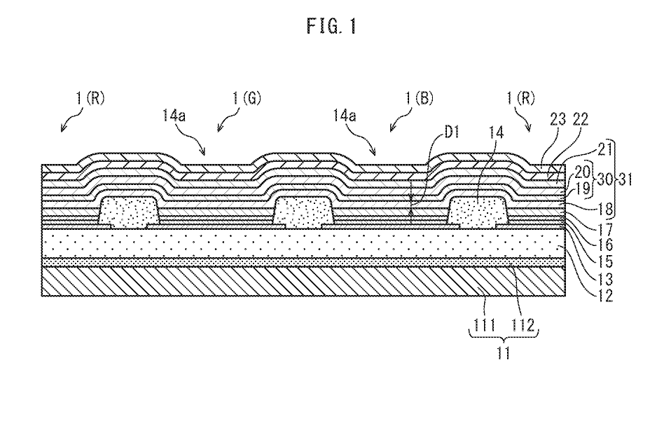

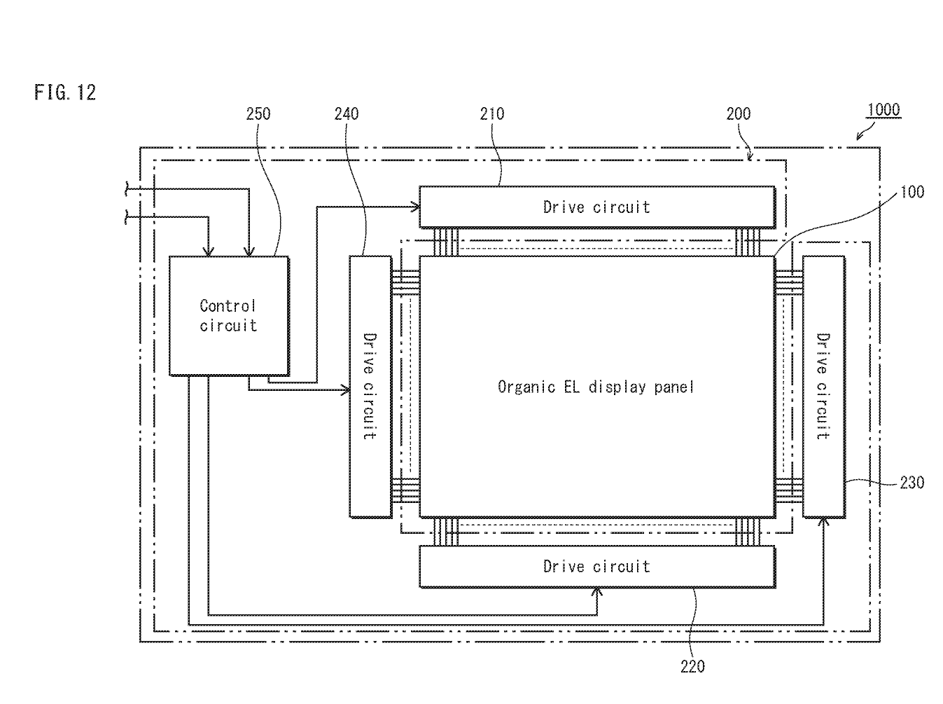

FIG. 1 is a partial cross-sectional view showing an organic EL display panel 100 relating to the present embodiment (see FIG. 12 for the organic EL display panel 100). The organic EL display panel 100 includes a plurality of pixels each of which is composed of respective organic EL elements emitting light of three colors, namely organic EL elements 1(R), 1(G), and 1(B) emitting light of red, green, and blue colors, respectively. FIG. 1 shows the cross section of the blue organic EL element 1(B) and the periphery thereof.

In the organic EL display panel 100, the organic EL elements are of a so-called top-emission type according to which light is emitted forward (toward the upper side in FIG. 1).

The organic EL elements 1(R), 1(G), and 1(B) have substantially the same structure. Accordingly, these organic EL elements are hereinafter collectively explained as the organic EL elements 1.

As shown in FIG. 1, the organic EL elements 1 each include a substrate 11, an interlayer insulating layer 12, a pixel electrode 13, a barrier rib layer 14, a hole injection layer 15, a hole transport layer 16, a light-emitting layer 17, a functional layer 31, a counter electrode 22, and a sealing layer 23. Note that the substrate 11, the interlayer insulating layer 12, the functional layer 31, the counter electrode 22, and the sealing layer 23 are formed not for each of the organic EL elements 1, but for the entire organic EL elements 1 included in the organic EL display panel 100.

<Substrate>

The substrate 11 includes a base material 111 that is an insulating material and a thin film transistor (TFT) layer 112. The TFT layer 112 includes drive circuits formed therein each of the organic EL elements 1. The base material 111 is made for example of a glass material such as non-alkali glass, soda glass, non-fluorescent glass, phosphoric glass, boric gas, and quartz.

<Interlayer Insulating Layer>

The interlayer insulating layer 12 is formed on the substrate 11. The interlayer insulating layer 12 is provided in order to flatten unevenness on an upper surface of the TFT layer 112. The interlayer insulating layer 12 is made of a resin material such as a positive photosensitive material. Such a photosensitive material is acrylic resin, polyimide resin, siloxane resin, or phenol resin. Also, although not shown in the cross-sectional view in FIG. 1, the interlayer insulating layer 12 has a contact hole formed therein for each of the organic EL elements 1.

<Pixel Electrode>

The pixel electrode 13 includes a metal layer that is made of a light-reflective metal material. The pixel electrode 13 is formed on the interlayer insulating layer 12 for each of the organic EL elements 1, and is electrically connected with the TFT layer 112 via a corresponding contact hole.

In the present embodiment, the pixel electrode 13 functions as an anode.

Specific examples of the light-reflective metal material include silver (Ag), aluminum (Al), alloy of aluminum, molybdenum (Mo), alloy of silver, palladium, and copper (APC), alloy of silver, rubidium, and gold (ARA), alloy of molybdenum and chromium (MoCr), alloy of molybdenum and tungsten (MoW), and alloy of nickel and chromium (NiCr).

The pixel electrode 13 may be made only of the metal layer, or have the multilayer structure including a layer made of metal oxide such as ITO and IZO that is layered on the metal layer.

<Barrier Rib Layer>

The barrier rib layer 14 is formed on the pixel electrode 13 so as to expose a partial region of an upper surface of the pixel electrode 13 and cover a peripheral region of the partial region. The partial region of the upper surface of the pixel electrode 13 that is not covered with the barrier rib layer 14 (hereinafter, referred to as an opening) corresponds to a subpixel. In other words, the barrier rib layer 14 has an opening 14a that is provided for each subpixel.

In the present embodiment, at a part where the pixel electrode 13 is not formed, the barrier rib layer 14 is formed on the interlayer insulating layer 12. In other words, at a part where the pixel electrode 13 is not formed, a bottom surface of the barrier rib layer 14 is in contact with an upper surface of the interlayer insulating layer 12.

The barrier rib layer 14 is made for example of an insulating organic material such as acrylic resin, polyimide resin, novolac resin, and phenol resin. In the case where the light-emitting layer 17 is formed using an applying method, the barrier rib layer 14 functions as a structure for preventing overflow of an applied ink. In the case where the light-emitting layer 17 is formed using a vapor deposition method, the barrier rib layer 14 functions as a structure for placing a vapor deposition mask. In the present embodiment, the barrier rib layer 14 is made of a resin material such as a positive photosensitive resin material. Such a photosensitive resin material is acrylic resin, polyimide resin, siloxane resin, or phenol resin. In the present embodiment, phenol resin is used.

<Hole Injection Layer>

The hole injection layer 15 is provided on the pixel electrode 13 within the opening 14a in order to promote injection of holes from the pixel electrode 13 to the light-emitting layer 17. The hole injection layer 15 is made for example of oxide such as silver (Ag), molybdenum (Mo), chromium (Cr), vanadium (V), tungsten (W), nickel (Ni), and iridium (Ir) or a conductive polymer material such as polyethylenedioxythiophene (PEDOT). In the case where the hole injection layer 15 is made of metal oxide, the hole injection layer 15 has a function of assisting generation of holes and stably injecting the holes to the light-emitting layer 17. The hole injection layer 15 has a high work function. In the present embodiment, the hole injection layer 15 is made of a conductive polymer material such as polyethylenedioxythiophene (PEDOT).

Here, in the case where the hole injection layer 15 is made of oxide of transition metal, the hole injection layer 15 has a plurality of energy levels because oxide of transition metal has a plurality of oxidation numbers. This facilitates hole injection, and therefore reduces driving voltage.

<Hole Transport Layer>

The hole transport layer 16 is formed within the opening 14a. The hole transport layer 16 is made of a high-molecular compound that does not have hydrophilic group. Such a high-molecular compound is for example, polyfluorene, polyfluorene derivative, polyallylamine, or polyallylamine derivative.

The hole transport layer 16 has a function of transporting holes, which are injected by the hole injection layer 15, to the light-emitting layer 17.

<Light-Emitting Layer>

The light-emitting layer 17 is formed within the opening 14a. The light-emitting layer 17 has a function of emitting light of R, G, and B colors owing to recombination of holes and electrons. The light-emitting layer 17 is made of a known material. The known material is for example oxinoid compound, perylene compound, coumarin compound, azacouramin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, anthracene compound, cyanine compound, acridine compound, and metal complex of 8-hydroxyquinoline compound, metal complex of 2-2′-bipyridine compound, complex of a Schiff base and group III metal, oxine metal complex, fluorescent substance such as rare earth complex, or phosphor substance emitting phosphor light such as tris (2-phenylpyridine) iridium.

<Functional Layer>

The functional layer 31 includes an interlayer 18 (the fluorine compound layer in the present disclosure), an electron transport layer 30, and an electron injection layer 21.

The interlayer 18 is formed on the light-emitting layer 17, and is made of fluoride of a first metal selected from alkali metal and alkaline-earth metal.

Alkali metal includes lithium, sodium, potassium, rubidium, cesium, or francium. Alkaline-earth metal includes calcium, strontium, barium, and radium. A film made of the fluoride has a function of blocking impurities.

Accordingly, the interlayer 18 has a function of preventing impurities, which exist within or on respective surfaces of the light-emitting layer 17, the hole transport layer 16, the hole injection layer 15, and the barrier rib layer 14, from intruding into the functional layer 31 and the counter electrode 22.

The first metal should preferably be particularly Na or Li. The interlayer 18 should preferably be made of sodium fluoride (NaF) or lithium fluoride (LiF).

The electron transport layer 30 includes an organic material and a second metal. The organic material has a function of transporting electrons, which are injected by the counter electrode 22, to the light-emitting layer 17. The second metal is selected from alkali metal and alkaline-earth metal, and has a property of cleaving fluoride of the first metal (NaF).

The electron transport layer 30 is composed of a metal doped region 19 and a metal non-doped region 20. The metal doped region 19 is formed on the interlayer 18, and is made of an organic material having an electron transport property. The metal doped region 19 is doped with the second metal. The metal non-doped region 20 is layered on the metal doped region 19, and is made of an organic material having an electron transport property. The metal non-doped region 20 is not doped with the second metal. In the present embodiment, the metal doped region 19 corresponds to the first region of the electron transport layer 30, and the metal non-doped region 20 corresponds to the second region of the electron transport layer 30.

The organic material included in the electron transport layer 30 is for example a π-electron low molecular organic material such as oxadiazole derivative (OXD), triazole derivative (TAZ), and phenanthroline derivative (BCP, Bphen).

A metal is selected as the second metal from alkali metal (such as lithium, sodium, potassium, rubidium, and cesium) and alkaline-earth metal (such as magnesium, calcium, strontium, and barium) that has a property of cleaving the bond between the first metal and fluorine in the fluoride of the first metal included in the interlayer 18.

In the present embodiment, barium (Ba) belonging to alkaline-earth metal is used as the second metal. Ba is an element that has a property of cleaving the bond between Na and F in NaF to liberate Na.

A electron injection layer 21 is provided on the metal non-doped region 20 of the electron transport layer 30 in order to improve an electron injection property from the counter electrode 22 to the metal non-doped region 20. The electron injection layer 21 is made of material having an electron injection property such as lithium fluoride (LiF), NaF, and hydroxy-quinolinato-lithium (Liq).

<Counter Electrode>

The counter electrode 22 is provided for the entire subpixels in common, and functions as a cathode.

The counter electrode 22 includes a metal layer that is made of a metal material. This metal layer has a thin thickness of approximate 10 nm to 30 nm, and accordingly is light-transmissive. Although a metal material is light-reflective, it is possible to ensure a light-transmissive property by reducing the thickness of the metal layer to 30 nm or lower.

Accordingly, part of light emitted from the light-emitting layer 17 is reflected off the counter electrode 22, and residue of the light transmits through the counter electrode 22.

In this way, inclusion of the metal layer in the counter electrode 22 reduces a sheet resistance of the counter electrode 22. The thickness of the metal layer of 10 nm or more reduces a surface resistance (Rs) thereof to 10 Ω/sq or less.

Also, inclusion of the metal layer in the counter electrode 22 improves a resonance effect of an optical cavity that is formed between the pixel electrode 13 and the counter electrode 22.

The metal material of the metal layer is silver (Ag), Ag alloy mainly containing Ag, aluminum (Al), or Al alloy mainly containing Al. Ag alloy is for example magnesium-silver alloy (MgAg) or indium-silver alloy. Ag has basically a low resistance. Ag alloy should preferably be used because of having an excellent heat resistance and a corrosion resistance and being capable of maintaining an excellent electrical conductivity for a long term.

Al alloy is for example magnesium-aluminum alloy (MgAl) or lithium-aluminum alloy (LiAl).

Other examples of alloy include lithium-magnesium alloy and lithium-indium alloy.

The metal layer may be made only of an Ag layer or an MgAg alloy layer. Alternatively, the metal layer may have a multilayer structure including the Mg layer and the Ag layer (Mg/Ag) or a multilayer structure including an MgAg alloy layer and the Ag layer (MgAg/Ag).

Further, the counter electrode 22 may be made only of the metal layer, or have a multilayer structure including a layer made of metal oxide such as ITO and IZO that is layered on the metal layer.

<Sealing Layer>

The sealing layer 23 is provided on the counter electrode 22 in order to suppress degradation of the light-emitting layer 17 due to exposure to moisture, oxygen, and so on. Since the organic EL display panel 100 is of the top-emission type, the sealing layer 23 is made of a light-transmissive material such as silicon nitride (SiN) and silicon oxynitride (SiON).

<Others>

Although not shown in FIG. 1, a color filter, an upper substrate, and so on may be adhered onto the sealing layer 23 via sealing resin. Adherence of the upper substrate protects the hole transport layer 16, the light-emitting layer 17, and the functional layer 31 against moisture, air, and so on.

[2. Property of Blocking Impurities and Electron Injection Property]

In the case where the hole injection layer 15, the hole transport layer 16, and the light-emitting layer 17 are formed by a wet process, when impurities, which exist within or on the respective surfaces of these layers, reach the electron transport layer 30, the impurities react with metal with which the organic material included in the electron transport layer 30 is doped, and thereby degrades the function of the electron transport layer 30.

Also, when the impurities react with the organic material, the organic material degrades and this might impair stability.

Also in the case where the barrier rib layer 14 is formed by the wet process, impurities, which exist within or on the surface of the barrier rib layer 14, similarly degrade the function of the electron transport layer 30.

In view of this, the organic EL element 1 relating to the present embodiment includes the interlayer 18 between the light-emitting layer 17 and the electron transport layer 30, and the interlayer 18 includes fluoride of an alkali metal or fluoride of an alkaline-earth metal. Accordingly, this fluoride prevents intrusion of the impurities from the light-emitting layer 17 into the electron transport layer 30.

Especially, NaF has an excellent property of blocking impurities because of having a low hygroscopicity and a low reactivity with oxygen, and accordingly prevents intrusion of the impurities from the light-emitting layer 17. This prevents reaction of alkali metal or alkaline-earth metal included in the electron transport layer 30 with impurities, and suppresses degradation of an electron supply property of the electron transport layer 30, and further prevents degradation of the counter electrode 22 due to impurities.

On the other hand, NaF has a high electron insulating property, and this causes a problem that NaF blocks movement of electrons, which are supplied from the counter electrode 22 and the electron transport layer 30, to the light-emitting layer 17, and as a result degrades luminous efficiency. In view of this, in the organic EL element 1, the electron transport layer 30 includes the metal doped region 19, which is doped with Ba as the second metal and is adjacent to the interlayer 18. Ba has a function of cleaving the bond between Na and F in fluoride of Na (NaF), which is fluoride of the first metal included in the interlayer 18. Accordingly, part of NaF in the interlayer 18 dissociates and Na is liberated.

Na has a low work function and a high electron supply property, and accordingly assists movement of electrons from the electron transport layer 30 to the light-emitting layer 17. This suppresses degradation of the luminous efficiency and reduces the driving voltage. Also, NaF in the interlayer 18 exhibits a more excellent property of blocking impurities.

The metal doped region 19 of the electron transport layer 30 should preferably have a Ba doping concentration of 5 wt % to 40 wt % in order to exhibit an excellent luminous efficiency.

For the purpose of cleaving the bond of NaF in the interlayer 18 to liberate Na, the metal doped region 19 of the electron transport layer 30 should preferably have a comparatively high Ba doping concentration within the range of 5 wt % to 40 wt %, specifically a Ba doping concentration of 20 wt % to 40 wt %.

Note that the mechanism that cleaves the bond between the first metal and fluorine in the fluoride of the first metal is not limited to the above. Any mechanism may cleave the bond between the first metal and fluorine unless the mechanism impairs the functions of the light-emitting layer 17, the interlayer 18, the electron transport layer 30, and so on.

As described above, the interlayer 18 includes the fluoride of the first metal, which has a high property of blocking impurities, and accordingly prevents intrusion of impurities from the light-emitting layer 17, and suppresses degradation of the electron supply property of the electron transport layer 30 (and the counter electrode 22). Also, the metal doped region 19 of the electron transport layer 30 includes the second metal, which cleaves the bond between the first metal and fluorine. Accordingly, the first metal is liberated, and this facilitates electrons to move from the electron transport layer 30 to the light-emitting layer 17 through the interlayer 18 which has a high insulating property. As a result, an excellent luminous efficiency is exhibited.

Note that there is a case where the actual boundary between the interlayer 18 and the metal doped region 19 of the electron transport layer 30 is not clearly defined, and material of the interlayer 18 and material of the metal doped region 19 of the electron transport layer 30 are mixed together to a certain degree during the manufacturing process thereof. That is, the interlayer 18 does not necessarily have the precise thickness D1, and the boundary between the interlayer 18 and the electron transport layer 30 is unclear.

Even in this case, the concentration of the first metal in the interlayer 18 is higher in the light-emitting layer 17 than in the electron transport layer 30, and the concentration of the second metal is higher in the electron transport layer 30 than in the light-emitting layer 17. Accordingly, the above effect is exhibited.

Here, in the case where the interlayer 18 is formed by a method intended to form the interlayer 18 having the thickness D1, the formed interlayer 18 is regarded as having the thickness D1, if not actually having the thickness D1. The same applies to the thickness of other layers.

[3. Thickness of Interlayer and Storage Stability]

A test of storage stability was performed with respect to three specimens of the organic EL display panel 100. The three specimens differ from each other in the thickness D1 of the interlayer 18.

The respective three specimens include the interlayer 18 having the thickness D1 of 1 nm, 4 nm, and 10 nm.

In the test of storage stability with respect to each of the specimens, initial luminance was measured by applying current to the specimen, the specimen was stored in an atmosphere of 80 degrees C. for seven days, and then luminance was measured again by applying current to the specimen. Then, luminance retention [%] (ratio of the luminance after storage at a high temperature to the initial luminance) was measured with respect to the specimen.

The storage stability was assessed using the luminance retention after storage at a high temperature.

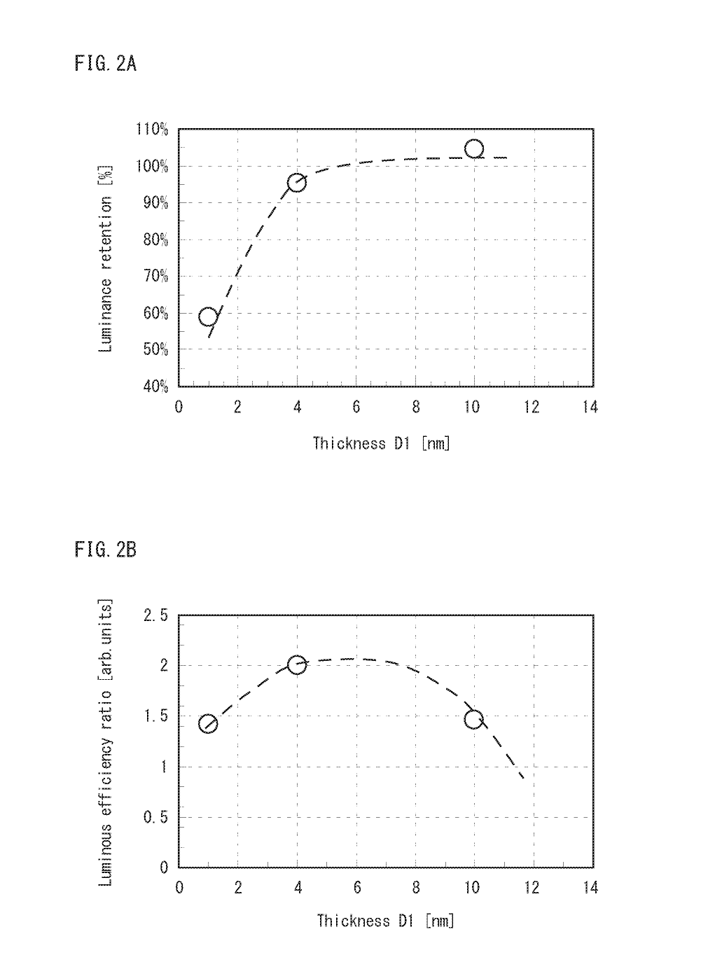

FIG. 2A is a graph showing results of the assessment.

As shown in FIG. 2A, with respect to the specimen including the interlayer 18 having the thickness D1 of 1 nm, a luminance retention of 59% was observed and a low storage stability was exhibited. With respect to the specimen including the interlayer 18 having the thickness D1 of 4 nm or more, a luminance retention of 95% or higher was observed and excellent storage stability was exhibited.

This demonstrates that it is possible to exhibit excellent storage stability, thereby prolonging the lifetime of the organic EL element, by including the interlayer 18 having the thickness D1 of 4 nm or more.

Note that a luminance retention of more than 100% was observed with respect to the specimen including the interlayer 18 having the thickness D1 of 10 nm. This is because it is considered that the balance between holes and electrons of the specimen, which has been in an inappropriate state before storage at a high temperature, became close to in an appropriate state owing to storage at the high temperature.

[4. Thickness of Interlayer and Luminous Efficiency Ratio]

FIG. 2B is a graph showing luminous efficiency ratio with respect to three specimens of the organic EL display panel 100. The three specimens differ from each other in the thickness D1 of the interlayer 18. The respective three specimens include the interlayer 18 having the thickness D1 of 1 nm, 4 nm, and 10 nm. Luminance was measured by applying voltage to each of the three specimens such that current density is 10 mA/cm², and luminous efficiency was calculated from the measured luminance. Then, a ratio of the calculated luminous efficiency to a reference value for luminous efficiency of the organic EL display panel (luminous efficiency ratio) was plotted on the graph.

As shown in FIG. 2B, the highest luminous efficiency ratio was observed with respect to the specimen including the interlayer 18 having the thickness D1 of 4 nm among the three specimens. Substantially the same luminous efficiency ratio was observed with respect to the respective specimens including the interlayer 18 having thickness D1 of 1 nm and 10 nm.

From the above results, it is considered that when the thickness D1 of the interlayer 18 is less than 1 nm and when the thickness D1 is more than 10 nm, a further low luminous efficiency ratio is observed. This is because of the following reasons. In the case where the thickness D1 of the interlayer 18 becomes excessively small, an absolute amount of the first metal (Na in the present embodiment) reduces and this hinders promotion of movement of electrons from the electron transport layer 30 to the light-emitting layer 17. On the other hand, in the case where the thickness D1 of the interlayer 18 is excessively large, the property of the interlayer 18 as an insulating film increases. This degrades the luminous efficiency.

Therefore, the thickness D1 of the interlayer 18 should preferably be 1 nm to 10 nm.

[5. Optical Thickness of Layers and Optical Cavity]

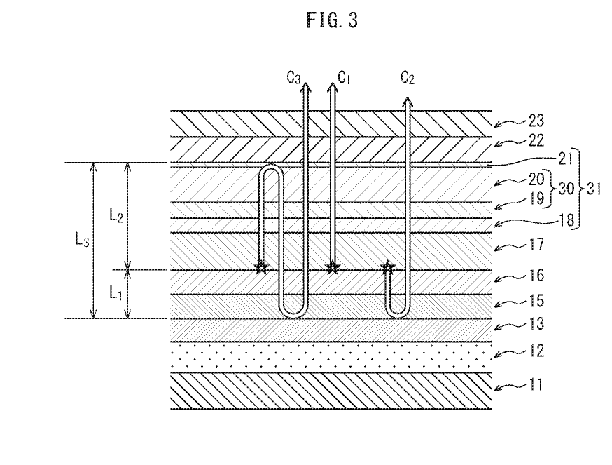

FIG. 3 explains optical interference that occurs in the optical cavity of the organic EL element relating to the present embodiment. The figure shows the organic EL element 1(B) including the light-emitting layer 17 emitting blue light, and explanation is provided here especially on the organic EL element 1(B).

In the optical cavity of the organic EL element 1(B), blue light is emitted from the vicinity of the interface of the light-emitting layer 17 with the hole transport layer 16, and transmits through the layers. Part of the light is reflected off the interface of each of the layers, and as a result optical interference occurs. The following exemplifies main types of optical interference.

(1) A first optical path C1 is formed in which part of light is emitted from the light-emitting layer 17 toward the counter electrode 22, transmits through the counter electrode 22, and is extracted to the outside of the organic EL element 1(B). A second optical path C2 is formed in which part of the light is emitted from the light-emitting layer 17 toward the pixel electrode 13, is reflected off the pixel electrode 13, then transmits through the light-emitting layer 17 and the counter electrode 22, and is extracted to the outside of the organic EL element 1(B). Then, interference occurs between direct light passing through the optical path C1 and reflected light passing through the optical path C2.

An optical thickness L1 shown in FIG. 3 corresponds to a difference in optical distance between the first optical path C1 and the second optical path C2. The optical thickness L1 is the total optical distance [nm] of the hole injection layer 15 and the hole transport layer 16, which are interposed between the light-emitting layer 17 and the pixel electrode 13 The optical distance of each of the layers is determined by a product of the film thickness by a refractive index.

(2) Further, a third optical path C3 is formed in which part of the light is emitted from the light-emitting layer 17 toward the counter electrode 22, is reflected off the counter electrode 22, is further reflected off the pixel electrode 13, and is extracted to the outside of the organic EL element 1(B).

Then, interference occurs between the light passing through the third optical path C3 and the light passing through the above second optical path C2.

An optical thickness L2 shown in FIG. 3 corresponds to a difference in optical distance between the second optical path C2 and the third optical path C3. The optical thickness L2 is the total optical distance of the light-emitting layer 17 and the functional layer 31.

Especially, in the organic EL element 1(B), since the counter electrode 22 includes the metal layer, light is easy to be reflected off the counter electrode 22 and therefore such interference tends to occur, compared with the case where the counter electrode 22 is made only of metal oxide.

(3) Moreover, interference occurs also between the light passing through the third optical path C3 and the light passing through the first optical path C1. An optical thickness L3 shown in FIG. 3 corresponds to a difference in optical distance between the first optical path C1 and the third optical path C3. The optical thickness L3 is the sum of the optical thickness L1 and L2 (L3=L1+L2).

Specifically, the optical thickness L3 is the total optical thickness of the hole injection layer 15, the hole transport layer 16, the light-emitting layer 17, and the functional layer 31, which are interposed between the pixel electrode 13 and the counter electrode 22.

In the optical cavity, the optical thickness is generally adjusted so as to correspond to a local maximum of light-extraction efficiency. The optical thickness L1 between the light-emitting layer 17 and the pixel electrode 13, the optical thickness L2 between the light-emitting layer 17 and the counter electrode 22, and the optical thickness L3 between the pixel electrode 13 and the counter electrode 22 are set such that the light passing through the above optical paths reinforces each other by the interference, and thereby improves the light-extraction efficiency.

Such basic optical interference similarly occurs in the red organic EL element 1(R) and the green organic EL element 1(G).

According to the inventors' study, in the case where the blue organic EL element is set to have an optical thickness corresponding to a local maximum of the light-extraction efficiency, chromaticity of extracted blue light is not close to a target chromaticity. It is preferable to set the optical thickness so as to correspond to a range of the light-extraction efficiency that is shifted from the local maximum of the light-extraction efficiency such that blue light having a low value y in the chromaticity is extracted.

In other words, in the optical cavity formed in the blue organic EL element 1(B), when the optical thickness L1 between the light-emitting layer 17 and the pixel electrode 13 and the optical thickness L2 between the light-emitting layer 17 and the counter electrode 22 are varied, not only the light-extraction efficiency of blue light but also the chromaticity vary.

In view of this, the blue organic EL element 1(B) is adjusted so as to have an optical thickness corresponding to a high ratio of the luminance to the value y in an x-y chromaticity (index luminance/y), as explained in detail below.

Generally, a target chromaticity of blue light that is finally extracted from the blue organic EL element 1(B) is a value y of 0.08 or lower in the x-y chromaticity.

In the case where the value y in the x-y chromaticity of blue light extracted from the blue organic EL element 1(B) is far from the target chromaticity, it is necessary to correct the chromaticity to a large degree with use of a color filter. In this case, there is no choice but to use the color filter with a low light transmissivity. As a result, the light-extraction efficiency of the blue light extracted from the blue organic EL element 1(B), which is originally high, degrades to a large extent after the blue light passes through the color filter.

Therefore, in order to effectively extract blue light having the value y in the chromaticity of approximately 0.08 or lower, it is necessary to take into consideration not only increase of the light-extraction efficiency but also decrease of the value y in the chromaticity. In other words, it is necessary to set the optical thickness of each layer included in the blue organic EL element 1(B) by taking into consideration both the light-extraction efficiency and the value y in the chromaticity.

As a result of further analysis, the inventors found that, in order to effectively extract blue light having the value y in the chromaticity of approximately 0.08 or lower, the optical thickness of each of the layers should be set such that a high value of the index luminance/y is achieved.

Based on this analysis, the index luminance/y is determined as an index with respect to the blue organic EL element 1(B), and the optical thickness L1 and L2 is set such that a high index is achieved. The following explains a specific example of the settings based on optical simulation.

(Optical Simulation)

With respect to the blue organic EL element 1(B) relating to an example in the present embodiment, the inventors performed simulation to calculate how the index luminance/y of blue light extracted from the blue organic EL element 1(B) varies in accordance with variation of each of the thickness of the hole transport layer 16 and the total thickness of the light-emitting layer 17 and the functional layer 31.

This simulation is known as an optical simulation using a matrix method.

In this simulation, a refractive index of light of 460 nm was used for refractive index of each of the layers included in the organic EL element 1(B). Also, the thickness of the counter electrode 22 was fixed to 30 nm, the thickness of the hole transport layer 16 was varied from 5 nm to 200 nm, and the total thickness of the light-emitting layer 17 and the functional layer 31 was varied from 10 nm to 200 nm.

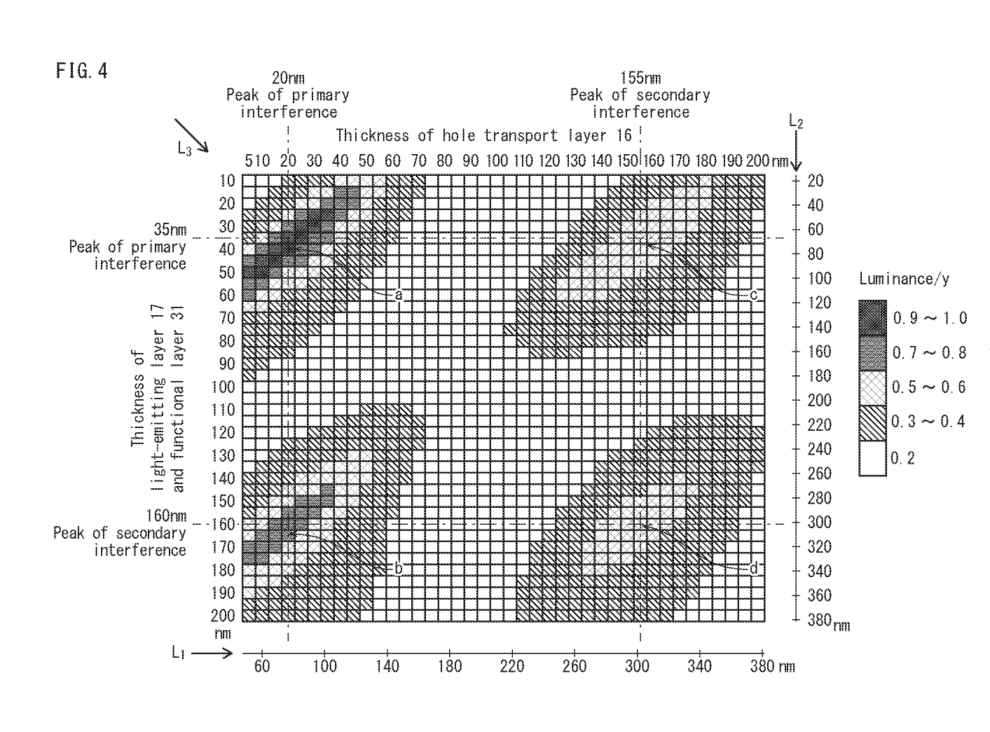

A graph in FIG. 4 has a horizontal axis representing the thickness of the hole transport layer 16 and a vertical axis representing the total thickness of the light-emitting layer 17 and the functional layer 31. The thickness was varied at 5 nm intervals.

Here, the optical thickness L1 is the total optical thickness of the hole transport layer 16, the hole injection layer 15, and the metal oxide layer included in the pixel electrode 13. Accordingly, in the case where the thickness of the hole injection layer 15 and the metal oxide layer included in the pixel electrode 13 is fixed, the optical thickness L1 varies in accordance with variation of the thickness of the hole transport layer 16. The horizontal axis in FIG. 4 also represents the optical thickness L1.

Similarly, the optical thickness L2 is the total optical thickness of the light-emitting layer 17 and the functional layer 31, and varies in accordance with variation of the total thickness of the light-emitting layer 17 and the functional layer 31. The vertical axis in FIG. 4 also represents the optical thickness L2.

The optical thickness L3 is the sum of the optical thickness L1 and L2, and accordingly increases in a diagonal direction indicated by an arrow L3 in FIG. 4.

The highest value of the index luminance/y was determined as 1, and relative values of the index luminance/y were mapped to separate numerical ranges (0.2, 0.3-0.4, 0.5-0.6, 0.7-0.8, and 0.9-1.0) in the graph.

In the graph in FIG. 4, a peak (local maximum) of the index luminance/y clearly appears at each of four intersection points (a, b, c, and d) between respective dashed lines, which indicate 20 nm and 155 nm as the thickness of the hole transport layer 16 and extend in the vertical direction, and respective dashed lines, which indicate 35 nm and 160 nm as the total thickness of the light-emitting layer 17 and the functional layer 31 and extend in the horizontal direction. That is, when the thickness of the hole transport layer 16 is 20 nm or 155 nm and the total thickness of the light-emitting layer 17 and the functional layer 31 is 35 nm or 160 nm, a local maximum of the index luminance/y appears.

When the thickness of any of the layers included in the organic EL element 1(B) is varied, a local maximum of the index luminance/y of extracted blue light appears. In the present Description, appearance of such a local maximum is represented as an interference, and as the thickness increases, the order of the interference increases. For example, a local maximum of the index luminance/y appears at the smallest thickness is a primary interference, and a local maximum of the index luminance/y appears at the second smallest thickness is a secondary interference.

In a relation between the index luminance/y and the optical thickness L1 (the thickness of the hole transport layer 16), a peak of the primary interference appears at the points a and b, and a peak of the secondary interference appears at the points c and d. The index luminance/y is higher at the peak of the primary interference than at the peak of the secondary interference. In a relation between the index luminance/y and the optical thickness L2 (the total thickness of the light-emitting layer 17 and the functional layer 31), the peak of the primary interference appears at the points a and c, and the peak of the secondary interference appears at the points b and d. The index luminance/y is higher at the peak of the primary interference than at the peak of the secondary interference.

Here, the peak of the primary interference corresponds to the smallest one among values of the optical thickness at which a local maximum of the index luminance/y appears, and the peak of the secondary interference corresponds to the second smallest one among the values of the optical thickness at which a local maximum of the index luminance/y appears.

The above simulation proves that it is possible to extract blue light having a higher index luminance/y from the organic EL element 1(B) not only by setting the optical thickness L1 so as to correspond to a peak of interference but also by setting the optical thickness L2 so as to correspond to a peak of interference.

The above simulation further proves that a high index luminance/y is obtained (high optical resonance effect is achieved) especially at the point a where both the peak of the primary interference relating to the optical thickness L1 and the peak of the primary interference relating to the optical thickness L2 appear.

Here, a high peak of the interference relating to the optical thickness L2 is considered to be caused by the metal layer included in the counter electrode 22. Accordingly, inclusion of the metal layer in the counter electrode 22 improves the optical resonance effect.

(Optical Thickness L2 and Index Luminance/y)

The following focuses on the optical thickness L2, and analyzes how the index luminance/y varies in accordance with variation of the optical thickness L2 while the optical thickness L1 is fixed to a constant value corresponding to the primary interference.

The optical thickness L1 corresponds to the primary interference when the thickness of the hole transport layer 16 is 20 nm, that is, when the optical thickness L1 is 76 nm, as shown in FIG. 4.

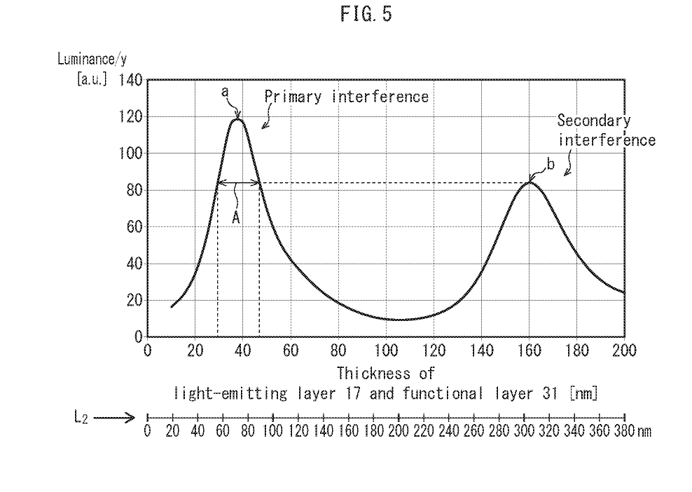

FIG. 5 is a graph showing results of simulation performed with respect to the index luminance/y of blue light extracted from the blue organic EL element 1(B) while varying the total thickness of the light-emitting layer 17 and the functional layer 31 from 5 nm to 200 nm. The optical thickness L2 has a value that is a product of the total thickness of the light-emitting layer 17 and the functional layer 31, which is represented in the horizontal axis, by a refractive index of 1.9.

As shown in the graph in FIG. 5, the peak of the primary interference and the peak of the secondary interference appear in an ascending order of the optical thickness L2. In an optical simulation, the local maximum of the index luminance/y at the peak a of the primary interference is higher than the local maximum of the index luminance/y at the peak b of the secondary interference.

Therefore, the results of the optical simulation prove that the index luminance/y of blue light extracted from the organic EL element 1(B) is increased by setting the thickness of the functional layer 31 so as to correspond to the peak of the primary interference. This allows effective extraction of blue light having an excellent chromaticity.

In optical simulation using the matrix method, however, decrease of the internal quantum efficiency is not reflected, which is caused by impurity level that occurs due to diffusion of Ag into the light-emitting layer 17 during the manufacturing process of the counter electrode 22, plasmon loss, and so on. The decrease of the internal quantum efficiency for the above causes is prominent in the organic EL element 1(B) including the light-emitting layer 17 emitting blue light. Also, in the case where the functional layer 31 has a large thickness and the light-emitting layer 17 is distant from the counter electrode 22, the decrease of the internal quantum efficiency for the above causes is not prominent.

In view of this, the inventors supposed that a difference exists between the thickness of the functional layer 31 which allows effective extraction of blue light having an excellent chromaticity from the organic EL element 1(B) and the preferable thickness of the functional layer 31 which was calculated based on the results of the optical simulation. Accordingly, the inventors made comparison in the index luminance/y between measured values of blue light emitted from the organic EL element 1(B) and the results of the optical simulation.

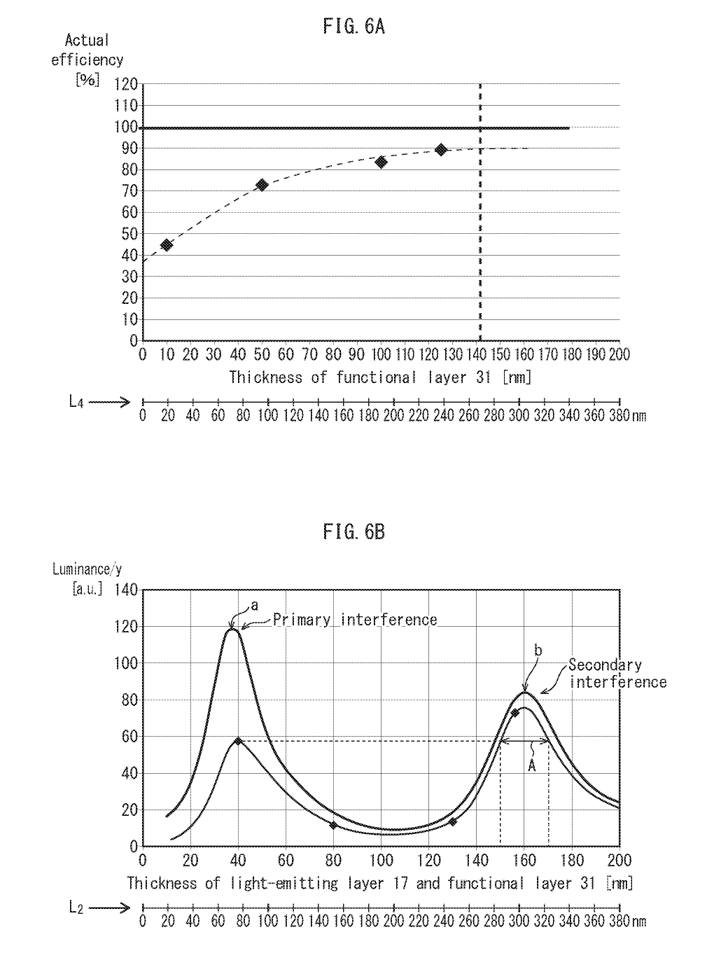

FIG. 6A shows results of the comparison.

FIG. 6A is a graph showing a ratio of the measured values to the results of the optical simulation with respect to four specimens of the organic EL element 1(B). The four specimens differ from each other in thickness of the functional layer 31. The respective four specimens of the organic EL element 1(B) include the functional layer 31 having thickness of 10 nm, 50 nm, 100 nm, and 125 nm. The optical thickness L1 of each of the four specimens of the organic EL element 1(B) was set to 76 nm corresponding to the primary interference.

With respect to each of the four specimens, the luminance and the value y were measured to calculate a measured value of the index luminance/y. Then, with respect to each of the specimens, a ratio of the measured value of the index luminance/y to the obtained value of the index luminance/y in the optical simulation was plotted in the graph. This ratio is hereinafter referred to as actual efficiency.

As shown in FIG. 6A, when the thickness of the functional layer 31 is 10 nm, the actual efficiency is 44%. There exists a great difference between the measured value and the results of the simulation. However, as the thickness of the functional layer 31 increases, the actual efficiency increases. When the thickness of the functional layer 31 is 125 nm, the actual efficiency is 89%. The measured value is close to the results of the simulation.

Since the functional layer 31 having a smaller thickness facilitates diffusion of Ag into the light-emitting layer 17 during the manufacturing process of the counter electrode 22 and increases the plasmon loss, the actual internal quantum efficiency is lower than the condition of the optical simulation. Conversely, as the functional layer 31 has a larger thickness, the functional layer 31 prevents diffusion of Ag into the light-emitting layer 17 during the manufacturing process of the counter electrode 22, and the light-emitting layer 17 is more distant from the counter electrode 22 and thereby the plasmon loss is reduced. This suppresses the difference between the actual internal quantum efficiency and the condition of the optical simulation. Accordingly, it is estimated that when the thickness of the functional layer 31 is 130 nm or larger, the actual efficiency is 90% or higher.

FIG. 6B is a graph showing a relation between the thickness of the functional layer 31 and the index luminance/y of blue light extracted from the blue organic EL element 1(B). In the graph, a bold line represents results of an optical simulation that is performed with respect to the index luminance/y of blue light extracted from the organic EL element 1(B) while varying the total thickness of the light-emitting layer 17 and the functional layer 31 from 5 nm to 200 nm. A thin line represents an index luminance/y of blue light that is estimated from the actual efficiency of each different value of the total thickness. The thickness of the light-emitting layer 17 included in each of the specimens was fixed to 50 nm.

As shown in the graph in FIG. 6B, also with respect to the index luminance/y of blue light estimated from the actual efficiency, a peak of a primary interference and a peak of a secondary interference appear in an ascending order of the thickness of the functional layer 31. This is the same as the results of the optical simulation.

However, with respect to the index luminance/y of blue light estimated from the actual efficiency, a local maximum of a peak a of the secondary interference is higher than a local maximum of a peak b of the primary interference. This is a difference from the results of the optical simulation.

Therefore, in consideration of the actual efficiency, the index luminance/y of blue light extracted from the organic EL element 1(B) is increased by setting the total thickness of the light-emitting layer 17 and the functional layer 31 so as to correspond to the peak of the secondary interference. This allows effective extraction of blue light having an excellent chromaticity.

Particularly, it is preferable to set the total thickness of the light-emitting layer 17 and the functional layer 31 so as to fall within a range A shown in the graph represented by the thin line in FIG. 6B in order to effectively extract blue light having an excellent chromaticity. The range A is included in a range of the total thickness of the light-emitting layer 17 and the functional layer 31 at which the peak of the secondary interference appears, and corresponds to the index luminance/y estimated from the actual efficiency that is higher than a local maximum of the index luminance/y estimated from the actual efficiency corresponding to the peak of the primary interference.

The range A is a range of the total thickness of the light-emitting layer 17 and the functional layer 31 from 150 nm to 170 nm. In the optical simulation whose results are shown in FIG. 6B, the thickness of the light-emitting layer 17 was fixed to 50 nm. Accordingly, the thickness of the functional layer 31 in the range A is 100 nm to 120 nm, and the optical thickness of the functional layer 31 is 100×1.9=190 nm to 120×1.9=228 nm.

Therefore, it is particularly preferable to set the optical thickness L1 to approximate 76 nm (for example, 60 nm to 90 nm), which corresponds to the primary interference, and set the optical thickness of the functional layer 31 to 190 nm to 228 nm in order to effectively extract blue light having an excellent chromaticity from the organic EL element 1(B).

FIGS. 5 and 6B show the results of the simulations with respect to when the optical thickness L1 corresponds to the peak of the primary interference (when the thickness of the hole transport layer 16 is 20 nm). Referring to FIG. 4, it is found that also when the optical thickness L1 corresponds to the peak of the secondary interference (also when the thickness of the hole transport layer 16 is 155 nm and the optical thickness L1 is 305.5 nm), a graph is obtained which shows an entirely low index luminance/y but has the similar shape as those in FIGS. 5 and 6B.

Therefore, it is also preferable to set the optical thickness L1 to approximate 305.5 nm (for example, 290 nm to 320 nm), which corresponds to the secondary interference, and set the optical thickness of the functional layer 31 to 190 nm to 228 nm in order to effectively extract blue light having an excellent chromaticity from the organic EL element 1(B).

In this way, it is preferable to set the optical thickness L1 to fall within a range appropriate for optical interference, and set the optical thickness of the functional layer 31 to 190 nm to 228 nm in order to effectively extract blue light having an excellent chromaticity from the organic EL element 1(B).

As explained above, with respect to the blue organic EL element 1(B), it is preferable to set the optical thickness L1 and the optical thickness of the functional layer 31 such that the index luminance/y increases. Also with respect to each of the organic EL element 1(R) and the organic EL element 1(B), it is preferable to similarly set the optical thickness L1 and the optical thickness of the functional layer 31 such that the luminance increases.

[6. Thickness of Electron Transport Layer]

As explained so far, the thickness D1 of the interlayer 18 should preferably be set to 1 nm to 10 nm. In other words, since the thickness of the interlayer 18 has a low proportion of the preferable total thickness of the functional layer 31 (100 nm to 120 nm), the thickness of the electron transport layer 30 needs to be increased in order to set the functional layer 31 so as to have a preferable thickness. For example, in the case where the thickness D1 of the interlayer 18 is set to 4 nm, the thickness of the electron transport layer 30 should preferably be set to 96 nm to 116 nm in order to set the thickness of the functional layer 31 to 100 nm to 120 nm.

Since the thickness of the electron transport layer 30 is increased in this way, the light-extraction efficiency of the organic EL element 1 is greatly affected by extinction coefficient of the electron transport layer 30. Especially in the case where the organic material included in the metal doped region 19 is doped with Ba at a concentration of 20%, the metal doped region 19 has a comparatively high extinction coefficient of 0.16.

On the other hand, since the organic material included in the metal non-doped region 20 is not doped with Ba, the metal non-doped region 20 has a low extinction coefficient of 0.034. Accordingly, it is preferable to reduce the thickness of the metal doped region 19 and increase the thickness of the metal non-doped region 20 in order to achieve a low extinction coefficient of the entire electron transport layer 30.

However, it is considered that if the thickness of the metal doped region 19 is excessively reduced, it is impossible to sufficiently dissociate NaF in the interlayer 18 adjacent to the metal doped region 19. In view of this, it is preferable to set the thickness of the metal doped region 19 to for example 10 nm to 30 nm, and then increase the thickness of the metal non-doped region 20 to the extent that the functional layer 31 has the preferable thickness.

Note that there is a case where the actual boundary between the metal doped region 19 and the metal non-doped region 20 is not clearly defined, and the metal doped region 19 and the metal non-doped region 20 are mixed together to a certain degree during the manufacturing process thereof. Even such a case, the concentration of the second metal is higher on the side of the interlayer 18 than on the side of the electron injection layer 21 in the electron transport layer 30. Therefore, it is possible to ensure the function of dissociating NaF in the interlayer 18 and achieve a low extinction coefficient of the entire electron transport layer 30.

[7. Manufacturing Method of Organic EL Element]

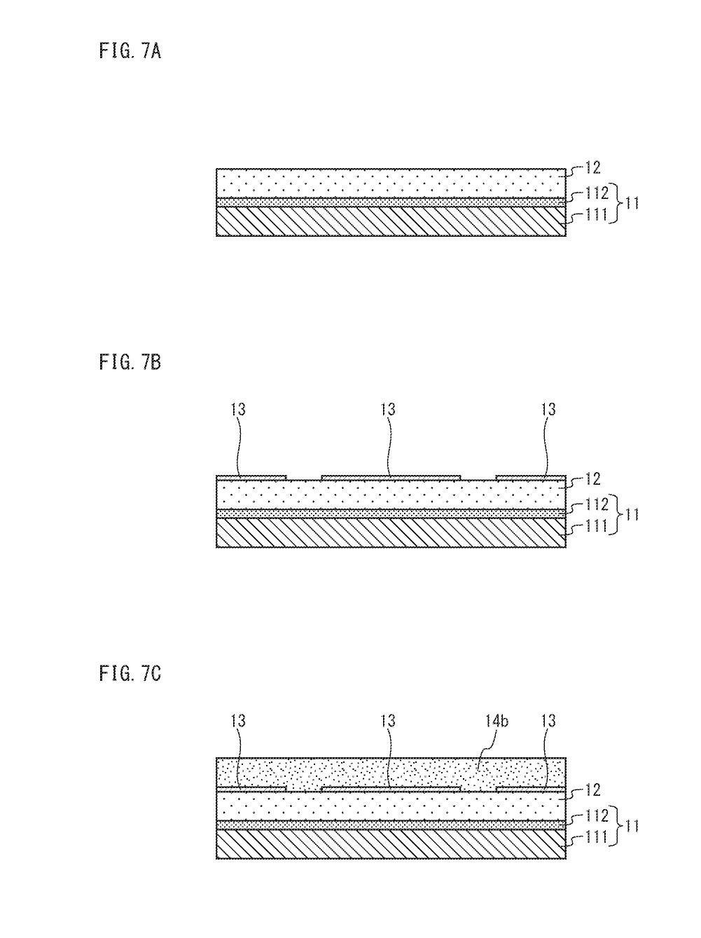

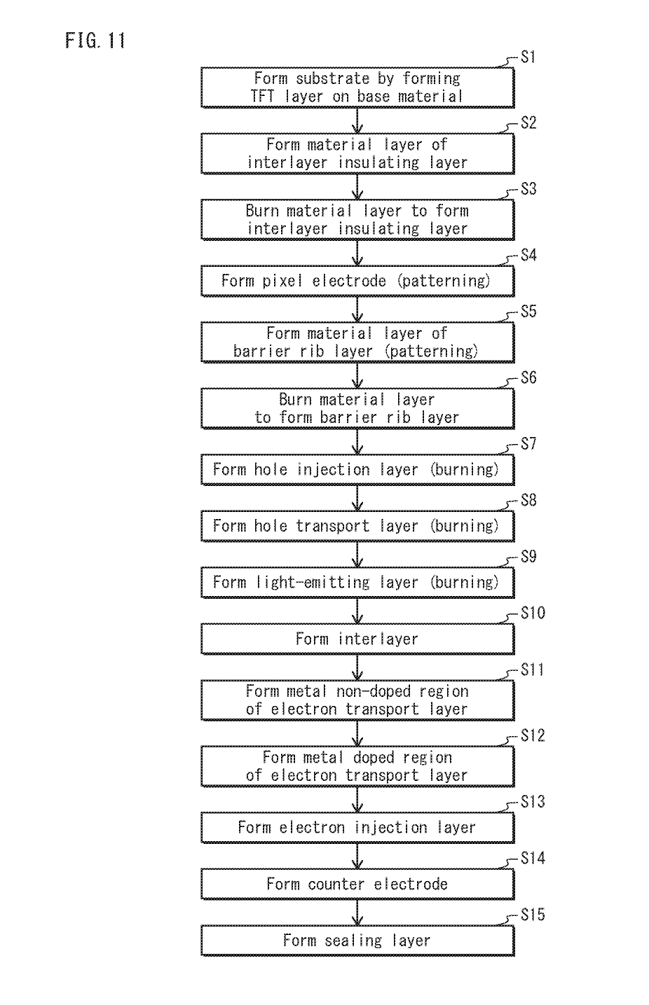

The following explains a manufacturing method of the organic EL element 1 with reference to FIGS. 7A-10D and 11. FIGS. 7A-10D are cross-sectional views schematically showing a manufacturing process of the organic EL element 1, and FIG. 11 is a flow chart schematically showing the manufacturing process of the organic EL element 1.

As shown in FIG. 7A, a substrate 11 is formed by forming a TFT layer 112 on a base material 111 (Step S1 in FIG. 11), and an interlayer insulating layer 12 is formed on the substrate 11 (Step S2 in FIG. 11). In the present embodiment, as a resin for an interlayer insulating layer that is a material of the interlayer insulating layer 12, acrylic resin, which is a positive photosensitive material, is used. The interlayer insulating layer 12 is formed by applying solution for the interlayer insulating layer onto the substrate 11, and burning the solution (Step S3 in FIG. 11). The solution for the interlayer insulating layer is solution in which acrylic resin, which is resin for interlayer insulating layer, is dissolved in solvent for the interlayer insulating layer such as PGMEA. Burning of the solution is performed at a temperature of 150 degrees C. to 210 degrees C. for 180 minutes.

Although not shown in the cross-sectional views in FIGS. 7A-10D and the flow chart in FIG. 11, while the interlayer insulating layer 12 is formed, a contact hole is formed by performing pattern exposure and developing. Since the interlayer insulating layer 12 becomes solid after burning, the contact hole is formed more easily before burning the interlayer insulating layer 12 than after burning the interlayer insulating layer 12.

Then, a pixel electrode 13 is formed for each subpixel as shown in FIG. 7B by forming a film having a thickness of approximate 150 nm from a metal material using a vacuum deposition method or a sputtering method (Step S4 in FIG. 11).

Next, a barrier rib material layer 14b is formed by applying a resin for a barrier rib layer that is a material of a barrier rib layer 14 onto the pixel electrode 13 (FIG. 7C). As the resin for the barrier rib layer, phenol resin, which is a positive photosensitive material, is for example used. The barrier rib material layer 14b is formed by uniformly applying, onto the pixel electrode 13, solution in which phenol resin, which is the resin for the barrier rib layer is dissolved in solvent (such as mixed solvent of ethyl lactate and GBL).

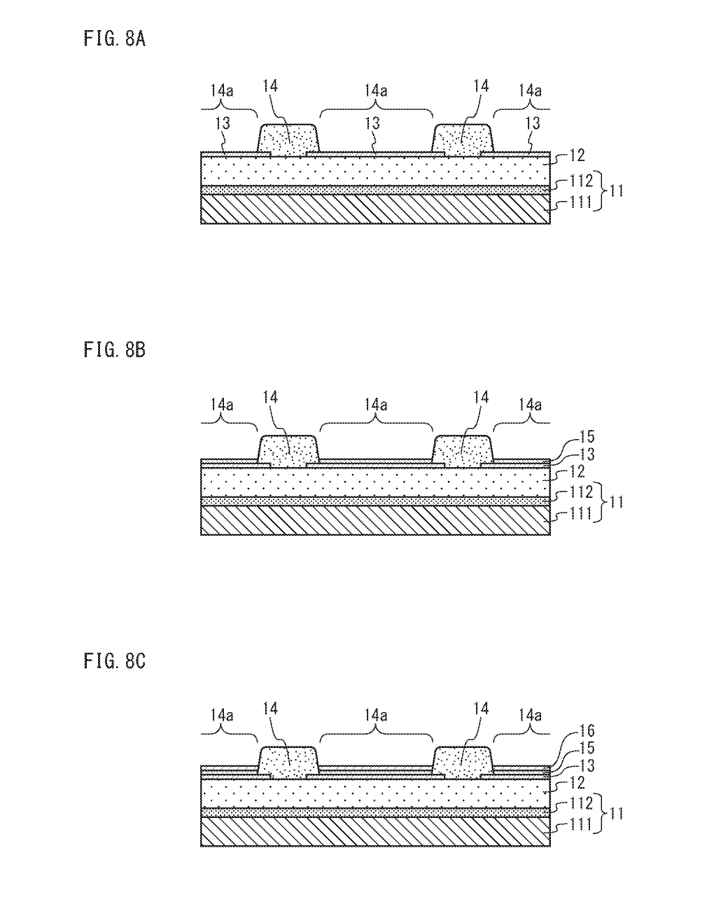

Next, the barrier rib layer 14 is formed by performing exposure and developing on the barrier rib material layer 14b to pattern the barrier rib material layer 14b to the shape of the barrier rib layer 14 (FIG. 8A and Step S5 in FIG. 11), and burning the barrier rib material layer 14b (Step S6 in FIG. 11). Burning of the barrier rib material layer 14b is performed for example at a temperature of 150 degrees C. to 210 degrees C. for 60 minutes. The barrier rib layer 14, which is formed, defines an opening 14a that is a region in which a light-emitting layer 17 is to be formed.

In a process of forming the barrier rib layer 14, a surface of the barrier rib layer 14 may undergo surface processing with use of predetermined alkaline solution, water, organic solvent, or the like, or plasma processing. Surface processing of the barrier rib layer 14 is performed in order to adjust a contact angle of the barrier rib layer 14 relative to ink to be applied to the opening 14a or to provide the surface of the barrier rib layer 14 with repellency.

Then, a hole injection layer 15 is formed as shown in FIG. 8B by forming a film from a material of the hole injection layer 15 using an applying method such as a mask vapor deposition method and an inkjet method, and burning the film (Step S7 in FIG. 11).

Next, a hole transport layer 16 is formed as shown in FIG. 8C by applying ink including a material of the hole transport layer 16 to the opening 14a defined by the barrier rib layer 14, and burning (and drying) the ink (Step S8 in FIG. 11).

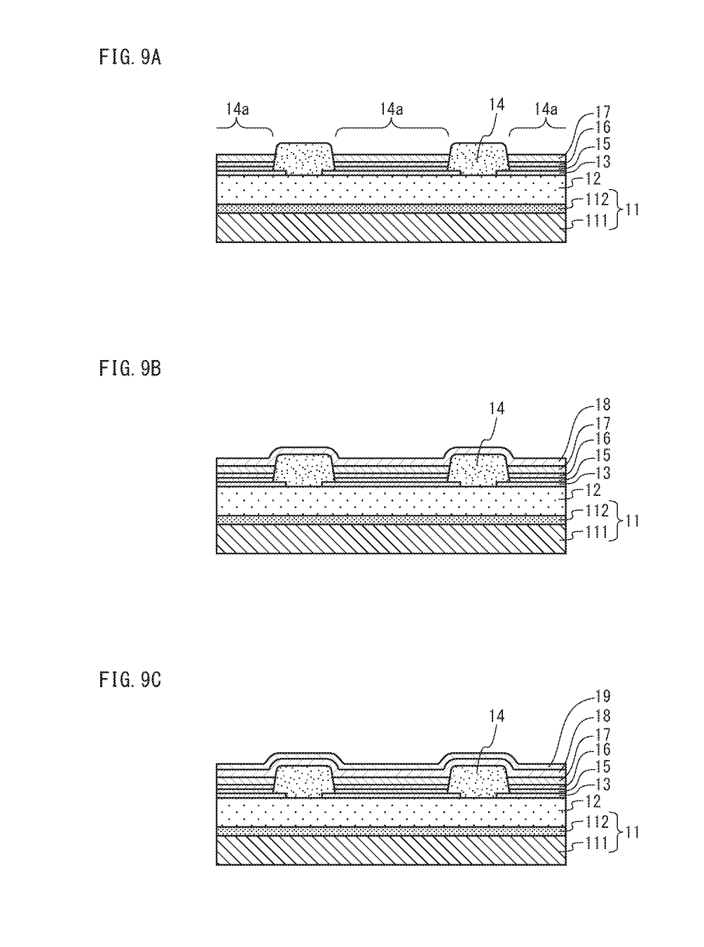

Similarly, the light-emitting layer 17 is formed as shown in FIG. 9A by applying ink including a material of the light-emitting layer 17, and burning (and drying) the ink (Step S9 in FIG. 11).

Then, as shown in FIG. 9B, an interlayer 18 having a thickness D1 is formed on the light-emitting layer 17 using the vacuum deposition method or the like (Step S10 in FIG. 11). The interlayer 18 is also formed on the barrier rib layer 14.

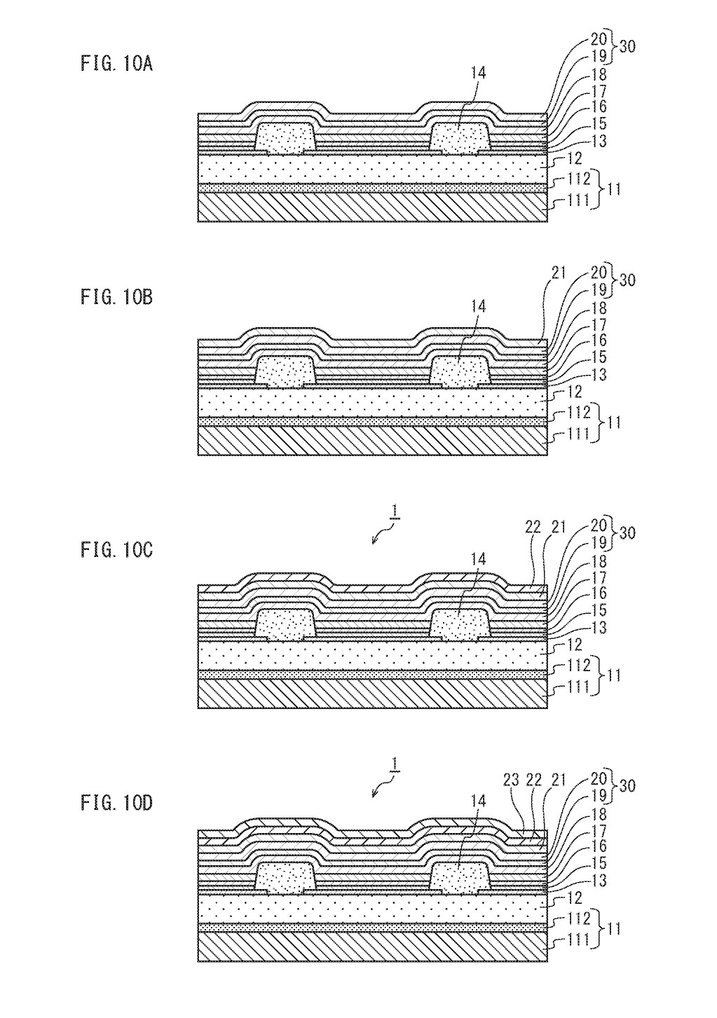

Next, a metal doped region 19 of the electron transport layer 30 is formed on the interlayer 18 as shown in FIG. 9C by forming a film from the organic material included in the electron transport layer 30 using the vacuum deposition method and doping the film with the second metal (Step S11 in FIG. 11). Further, a metal non-doped region 20 of the electron transport layer 30 is formed on the metal doped region 19 as shown in FIG. 10A by forming a film from the organic material included in the electron transport layer 30 using the vacuum deposition method without doping the film with the second metal (Step S12 in FIG. 11).

In a process of forming the metal doped region 19 and the metal non-doped region 20, an amount of the organic material and the second metal to be deposited using the vacuum deposition method is determined, such that the thickness of the electron transport layer 30, which includes the metal doped region 19 and the metal non-doped region 20, falls within a range of a result of subtraction of the thickness D1 of the interlayer 18 and the thickness of the electron injection layer 21 (0.5 nm to 1.0 nm), which is formed after forming the electron transport layer 30, from the preferable thickness range of the functional layer 31 (100 nm to 120 nm).

Next, an electron injection layer 21 is formed on the metal non-doped region 20 of the electron transport layer 30 as shown in FIG. 10B by forming a film from material of the electron injection layer 21 so as to have a thickness of 0.5 nm-1.0 nm using the vacuum deposition method or the sputtering method (Step S13 in FIG. 11).

Next, a counter electrode 22 is formed on the electron injection 21 as shown in FIG. 10C by forming a film from a metal material and so on using the vacuum deposition method, the sputtering method, or the like (Step S14 in FIG. 11).

Then, a sealing layer 23 is formed on the counter electrode 22 as shown in FIG. 10D by forming a film from a light-transmissive material such as SiN and SiON using the sputtering method, a CVD method, or the like (Step S15 in FIG. 11).

Through the above processes, an organic EL element 1 is complete, and an organic EL display panel 100 including a plurality of organic EL elements 1 is also complete. Note that a color filter, an upper substrate, and so on may be adhered onto the sealing layer 23.

[8. Overall Structure of Organic EL Display Device]

FIG. 12 is a block diagram schematically showing the overall structure of an organic EL display device 1000. As shown in the figure, the organic EL display device 1000 includes the organic EL display panel 100 and a drive control unit 200 that is connected to the organic EL display panel 100. The drive control unit 200 includes four drive circuits 210 to 240 and a control circuit 250.

In the actual organic EL display device 1000, the drive control unit 200 is not limited to this arrangement relative to the organic EL display panel 100.

### Summary of Embodiment

According to the organic EL element 1 relating to the present embodiment, the interlayer 18 prevents intrusion of impurities from the light-emitting layer 17 into the electron transport layer 30. Therefore, it is possible to suppress occurrence of an adverse effect such as degradation of the luminous efficiency and reduction of the light-emitting lifetime.

Also, the metal doped region 19, which is in contact with the interlayer 18, includes Ba, and accordingly ensures an electron injection property from the interlayer 18 to the light-emitting layer 17. This exhibits a high internal quantum efficiency.

Also, the metal non-doped region 20 of the electron transport layer 30 is not doped with Ba, and accordingly has a low extinction coefficient of 0.034. Further, the thickness of the metal non-doped region 20, which has a low extinction coefficient, is increased while reducing the thickness of the metal doped region 19, which has a high extinction coefficient due to doping with Ba, to 10 nm to 30 nm. This achieves a low extinction coefficient of the entire electron transport layer 30, and thereby exhibits an excellent light-extraction efficiency.

Also, the functional layer 31 included in the blue organic EL element 1(B) emitting blue light is set to have a thickness of 100 nm to 120 nm. This thickness range of the functional layer 31 corresponds to the peak of the secondary interference of blue light, and is larger than a thickness range corresponding to the peak of the primary interference. This suppresses diffusion of Ag during the manufacturing process of the counter electrode 22 and plasmon loss, and thereby improves internal quantum efficiency. As a result, it is possible to effectively extract blue light having an excellent color purity and corresponding to an index luminance/y that is equal to or higher than the local maximum of the index luminance/y at the primary interference.

Further, the counter electrode 22 has a reduced sheet resistance by including therein the metal layer, which is made of the metal material such as Ag, compared with the case where the counter electrode 22 is made only of a metal oxide material such as ITO. Then, improvement of conductivity of the counter electrode 22 reduces decrease of voltage during supply of power to the organic EL element 1, which is disposed on the center part of the organic EL display panel 100.

Further, inclusion of the metal layer in the counter electrode 22 improves the resonance effect of the optical cavity formed in the organic EL element 1, compared with the case where the counter electrode 22 is made only of the metal oxide material. As a result, the light-extraction efficiency of the organic EL element 1 is improved.

Note that the conditions for the values and the ratio of the thickness in the above explanation do not necessarily need to be satisfied with respect to the whole region of each subpixel defined by the opening 14a, and only need to be satisfied with respect to the center part of the subpixel.

<Modifications>

Although the explanation has been given on the embodiment, the present disclosure is not limited to the embodiment. The following modifications for example may be made.

(Modification 1) The organic EL element relating to the above embodiment includes the hole injection layer 15 and the hole transport layer 16. Alternatively, an organic EL element that does not include at least one of these layers may be similarly embodied.

(Modification 2) In the above embodiment, the explanation has been given on the example in which glass is used as the insulating material of the base material 111 included in the organic EL element 1. However, the insulating material of the base material 111 is not limited to this. Alternatively, resin, ceramic, or the like may be used as the insulating material of the base material 111. Examples of the resin used for the base material 111 include polyimide resin, acrylic resin, styrene resin, polycarbonate resin, epoxy resin, polyethersulfone, polyethylene, polyester, and silicone resin. Examples of ceramic used for the base material 111 include aluminum.

(Modification 3) In the above embodiment, the organic EL display panel 100 is of the top-emission type according to which the pixel electrode 13 is a light-reflective anode and the counter electrode 22 is a light-transmissive cathode. Alternatively, the organic EL display panel may of the bottom-emission type according to which a pixel electrode is a light-transmissive cathode and a counter electrode is a light-reflective anode.

In this case, the organic EL display panel has the following structure for example. The pixel electrode 13 as a cathode and the barrier rib layer 14 are formed on the interlayer insulating layer 12. Within the opening 14a, the electron injection layer 21, the metal non-doped region 20 of the electron transport layer 30, the metal doped region 19 and of the electron transport layer 30, the interlayer 18, and the light-emitting layer 17 are formed on the pixel electrode 13 in respective order. The hole transport layer 16 and the hole injection layer 15 are formed on the light-emitting layer 17 in respective order. The counter electrode 22 as an anode is formed on the hole injection layer 15.

(Modification 4) In the above embodiment, the explanation has been given on the example in which the metal non-doped region 20 of the electron transport layer 30 does not include the second metal. Alternatively, the metal non-doped region 20 may include the second metal. In the case where the metal non-doped region 20 of the electron transport layer 30 includes the second metal, the metal non-doped region 20 is set to have a lower concentration of the second metal than the metal doped region 19.

For example, in the case where the electron transport layer 30 is doped with Ba, the metal doped region 19 should preferably have a Ba doping concentration of 20 wt % to 40 wt % in order to cleave the bond of NaF in the interlayer 18 to liberate Na, and the metal non-doped region 20 should have a Ba doping concentration of 5 wt % to 19 wt %.

In the case where the metal non-doped region 20 is set to have a Ba doping concentration of 5 wt % to 19 wt %, an electron injection property from the counter electrode 22 to the metal non-doped region 20 is ensured. In this case, the electron injection layer 21 may not need to be included in the functional layer 31.

The organic EL element and the organic EL display panel relating to the present disclosure are utilizable for displays for use in various types of display devices for households, public facilities, and business, displays for television devices, portable electronic devices, and so on.

Although the technology pertaining to the present disclosure has been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. An organic EL element comprising:
a light-reflective anode;
a light-emitting layer that is disposed above the anode;
a functional layer that is disposed on the light-emitting layer; and
a light-transmissive cathode that is disposed on the functional layer, and includes a metal layer, wherein
the functional layer includes:
a fluorine compound layer that includes a fluorine compound including a first metal that is an alkali metal or an alkaline-earth metal; and
an electron transport layer that is disposed on the fluorine compound layer, and has an electron transport property,
the electron transport layer includes an organic material, and is doped with a second metal, the organic material having an electron transport property, the second metal being an alkali metal or an alkaline-earth metal,
the electron transport layer has a first region and a second region,
the first region is in contact with the fluorine compound layer, and the second region is closer to the cathode than the first region is, and
the first region has a concentration of the second metal higher than the second region has.

2. The organic EL element of claim 1, wherein
the first region includes the second metal, and
the second region does not include the second metal.

3. The organic EL element of claim 2, wherein
the first metal is sodium.

4. The organic EL element of claim 3, wherein
the second metal has a property of cleaving a bond between the first metal and fluorine in the fluorine compound including the first metal.

5. The organic EL element of claim 3, wherein
the second metal is barium.

6. The organic EL element of claim 2, wherein
the light-emitting layer emits blue light,
an optical cavity is formed between the anode and the cathode, and
the functional layer has a thickness at which a secondary interference of the blue light occurs in the optical cavity.

7. The organic EL element of claim 6, wherein
the thickness of the functional layer is set so as to correspond to an index luminance/y that is equal to or higher than a local maximum of the index luminance/y at a primary interference according to characteristics of the index luminance/y that varies in accordance with variation of the thickness of the functional layer, where luminance and y are luminance and a value y in an x-y chromaticity of the blue light extracted from the organic EL element, respectively.

8. The organic EL element of claim 2, wherein
the functional layer further includes
an electron injection layer that is disposed on the electron transport layer, and has an electron injection property.

9. A manufacturing method of an organic EL element comprising:
forming a light-reflective anode;
forming, above the anode, a light-emitting layer;
forming, on the light-emitting layer, a fluorine compound layer that includes a fluorine compound including a first metal that is an alkali metal or an alkaline-earth metal;
forming, on the fluorine compound layer, an electron transport layer from an organic material that has an electron transport property; and
forming, above the electron transport layer, a light-transmissive cathode that includes a metal layer, wherein
in the forming the electron transport layer, a first region of the electron transport layer is doped with a second metal at a higher concentration than a second region of the electron transport layer is, the first region being in contact with the fluorine compound layer, and the second region being above the first region, the second metal being an alkali metal or an alkaline-earth metal.
